(19) United States
(12) Patent Application Publication
(10) Pub. No.: US 2017/0178780 A1
(43) Pub. Date: Jun. 22, 2017

(54) A MULTIFERROIC LAMINATED STRUCTURE, A SWITCHING ELEMENT, A MAGNETIC DEVICE AND A METHOD FOR MANUFACTURING A LAMINATED STRUCTURE

(71) Applicant: TOKYO INSTITUTE OF TECHNOLOGY, Tokyo (JP)

(72) Inventors: Tomoyasu TANIYAMA, Tokyo (JP); Yasuhiro SHIRAHATA, Tokyo (JP); Ryota SHIINA, Tokyo (JP)

(73) Assignee: TOKYO INSTITUTE OF TECHNOLOGY, Tokyo (JP)

(21) Appl. No.: 15/120,697

(22) PCT Filed: Feb. 27, 2015
(86) PCT No.: PCT/JP2015/055885

§ 371 Date: Aug. 22, 2016

(30) Foreign Application Priority Data
Feb. 27, 2014 (JP) 2014-036216

(51) Int. Cl. H01F 10/14; H01F 41/22; H01F 10/32

(52) U.S. Cl. CPC H01F 10/14; H01F 10/324; H01F 41/22; H01L 43/10

(57) ABSTRACT

More stable perpendicular magnetization orientation is attained, and switching of the magnetization orientation between an out-of-plane direction and an in-plane direction is enabled by voltage. A multiferroic laminated structure having ferroelectricity and ferromagnetism includes: a ferroelectric layer made of a ferroelectric substance having the ferroelectricity; a foundation layer composed mainly of a metal having a good lattice-matching property with the ferroelectric substance and laminated on a surface of the ferroelectric layer; an intermediate layer composed mainly of a non-magnetic substance and laminated on a surface of the foundation layer; and a ferromagnetic/non-magnetic multilayer film layer constituted by alternately laminating ferromagnetic layers and non-magnetic layers on a surface of the intermediate layer in at least three cycles, the ferromagnetic layers being composed mainly of a ferromagnetic substance, the non-magnetic layers being composed mainly of the non-magnetic substance.

### BACKGROUND OF THE INVENTION

Field of the Invention

The present invention relates to a multiferroic laminated structure having both ferroelectricity and ferromagnetism, a switching element including such a laminated structure, a magnetic device including such a switching element, and a method for manufacturing such a laminated structure. The present application claims priority based on the Japanese Patent Application No. 2014-036216 filed on Feb. 27, 2014 in Japan, which is incorporated by reference herein.

Description of Related Art

Conventionally, the mainstream of techniques for magnetization orientation control in magnetic devices such as magnetic random access memory (MRAM), magnetic heads, and spin transistors has been methods that involve the use of magnetic fields. Moreover, in recent years, attempts have been proposed to achieve such magnetization orientation control with electric currents toward magnetic devices with increasingly greater densities. However, the manipulation of magnetic bits by electric currents requires a tremendous electric current density and therefore makes it necessary to overcome problems such as generation of heat.

For this reason, in the development of ever-denser magnetic devices, technologies for controlling magnetization orientation with voltage alone without using electric currents have been under vigorous development. As magnetization orientation control with use of voltage, there has been proposed a method for voltage-controlling an electron state at a junction interface between a Fe magnetic ultra-thin film and MgO. However, since a single-layer magnetic film is used as the magnetic thin film and the electric control of coercivity of perpendicular magnetization requires a high electric field in megaunits (MV/cm) or larger, it has been difficult to completely convert magnetization orientation with voltage.

As another method for lowering power consumption by controlling magnetization orientation with voltage, there has been proposed a method for voltage-controlling a magnetostrictive effect at a junction interface between a magnetic thin film and a ferroelectric substance. For example, Patent Literature 1 discloses a method in which a heterostructure including a single-crystal ferroelectric layer and a ferromagnetic layer epitaxially grown on top of the ferroelectric layer is prepared and the magnetization orientation of the ferromagnetic substance is changed by a strain that is generated at a junction interface between the ferroelectric layer and the ferromagnetic layer by applying voltage to the ferroelectric layer.

Patent document 1: Japanese Patent Application Laid-Open No. 2012-119565

### BRIEF SUMMARY OF THE INVENTION

Magnetic recording media on which information is recorded by the orientation state of magnetization of a magnetic material, such as magnetic recording media and magneto-optical recording media, and recording and reproducing apparatuses therefor have drawn attention as rewritable high-density recording media and recording and reproducing apparatuses therefor. Further, there has been a growing demand for achieving recording media with further increases in capacity by increasing the recording densities of these magnetic recording media. For this reason, increasing the recording density of a magnetic recording medium by switching from a longitudinal magnetic recording mode having in-plane magnetization orientation to a perpendicular magnetic recording mode having perpendicular magnetization orientation has drawn attention as a magnetic recording medium on which information is recorded by the orientation state of magnetization of a magnetic material.

That is, a further increase in recording density of a magnetic device such as a magnetic recording medium requires magnetization orientation control not only in the plane of a magnetic material but also in a direction perpendicular to the magnetic material and the switchability of magnetization orientation of the magnetic material between the in-plane direction and the perpendicular direction. Patent Literature 1, which discloses the magnetic anisotropic control method, refers to electrically controlling magnetization orientation in the in-plane direction, but does not refer to switching magnetization orientation between the in-plane direction and the perpendicular direction with voltage.

The present invention has been made in view of the foregoing problems, and it is an object of the present invention to provide a novel and improved laminated structure, switching element, magnetic device, and method for manufacturing a laminated structure that attain magnetization orientation that is stable in the perpendicular direction and make it possible to switch the magnetization orientation between the perpendicular direction and the in-plane direction with voltage.

An aspect of the present invention is a multiferroic laminated structure having ferroelectricity and ferromagnetism, comprising: a ferroelectric layer made of a ferroelectric substance having the ferroelectricity; a foundation layer composed mainly of a metal having a good lattice-matching property with the ferroelectric substance and laminated on a surface of the ferroelectric layer; an intermediate layer composed mainly of a non-magnetic substance and laminated on a surface of the foundation layer; and a ferromagnetic/non-magnetic multilayer film layer constituted by alternately laminating ferromagnetic layers and non-magnetic layers on a surface of the intermediate layer in at least three cycles, the ferromagnetic layers being composed mainly of a ferromagnetic substance, the non-magnetic layers being composed mainly of the non-magnetic substance.

The first aspect of the present invention makes it possible to surely form a multiferroic laminated structure including a multilayer film layer having magnetization orientation that is stable in a perpendicular direction.

In addition, in an aspect of the present invention, the ferroelectric substance constituting the ferroelectric layer is barium titanate, the metal constituting the foundation layer is iron, the non-magnetic substance constituting the intermediate layer and the non-magnetic layers is copper, and the ferromagnetic substance constituting the ferromagnetic layers is nickel.

In this way, a multiferroic laminated structure including a multilayer film layer having magnetization orientation that is stable in the perpendicular direction can be easily formed by epitaxial growth.

In addition, in an aspect of the present invention, the multilayer film layer is configured such that the non-magnetic layers are larger in thickness than the ferromagnetic layers.

In this way, a surface strain of the ferromagnetic layer can be made larger. This makes it possible to more surely achieve a crystal structure having magnetization orientation that is stable in the perpendicular direction.

Another aspect of the present invention is a switching element comprising: electrodes connected to a power supply; and any of the laminated structures described above provided between the electrodes.

The second aspect of the present invention makes it possible to surely form a switching element which includes a multilayer film layer having magnetization orientation that is stable in the perpendicular direction and which is capable of controlling switching of the magnetization orientation from the perpendicular direction to an in-plane direction through voltage application.

In addition, in another aspect of the present invention, application of voltage from the power supply enables switching of magnetization orientation of a multilayer film layer included in the laminated structure and composed of ferromagnetic layers and non-magnetic layers.

In this way, the perpendicular magnetization orientation of the multilayer film layer including the ferromagnetic layers can switched to the in-plane direction with lower power consumption.

In addition, in another aspect of the present invention, a magnetic field whose strength continuously varies in a predetermined direction is further applied to the multilayer film layer, and when the strength of the magnetic field takes on a predetermined negative minute value, application of voltage from the power supply enables switching of magnetization orientation of the multilayer film layer.

In this way, the perpendicular magnetization orientation of the multilayer film layer including the ferromagnetic layers can be reversed 180 degrees by voltage application.

In addition, in another aspect of the present invention, a change of an environmental temperature at which the laminated structure is provided to a predetermined temperature enables switching of magnetization orientation of a multilayer film layer included in the laminated structure.

In this way, the magnetization orientation of the multilayer film layer can be switched between the perpendicular direction and the in-plane direction by controlling the environmental temperature at which the laminated structure is provided.

Another aspect of the present invention is a magnetic device comprising any of the switching elements described above.

According to the third aspect of the present invention, application to a magnetic device such as a magnetic recording medium of a switching element capable of switching magnetization orientation through voltage application makes it possible to increase the recording density of the magnetic device and lower power consumption.

In addition, in another aspect of the present invention, the switching element is provided in at least any of a magnetic head, a spin transistor, a polarization control light-emitting element, and a micromotor.

Application to such a magnetic device of a switching element capable of switching magnetization orientation through voltage application makes it possible to improve the performance of the magnetic device and lower power consumption.

Another aspect of the present invention is a method for manufacturing a multiferroic laminated structure having ferroelectricity and ferromagnetism, comprising: a heat treatment step of heat-treating a ferroelectric layer made of a ferroelectric substance having the ferroelectricity; a foundation layer lamination step of laminating a foundation layer on a surface of the ferroelectric layer by epitaxially growing the foundation layer, the foundation layer being composed mainly of a metal having a good lattice-matching property with the ferroelectric substance; an intermediate layer lamination step of laminating an intermediate layer on a surface of the foundation layer by epitaxially growing the intermediate layer, the intermediate layer being composed mainly of a non-magnetic substance; and a multilayer film layer lamination step of laminating a ferromagnetic/non-magnetic multilayer film layer on a surface of the intermediate layer by epitaxially growing the multilayer film layer, the multilayer film layer being constituted by alternately laminating ferromagnetic layers and non-magnetic layers in at least three cycles, the ferromagnetic layers being composed mainly of a ferromagnetic substance, the non-magnetic layers being composed mainly of the non-magnetic substance.

According to the fourth aspect of the present invention, a multiferroic laminated structure including a multilayer film layer having magnetization orientation that is stable in the perpendicular direction can be easily formed by epitaxial growth.

In addition, in another aspect of the present invention, the ferroelectric substance constituting the ferroelectric layer is barium titanate, the metal constituting the foundation layer is iron, the non-magnetic substance constituting the intermediate layer and the non-magnetic layers is copper, and the ferromagnetic substance constituting the ferromagnetic layers is nickel.

In this way, a multiferroic laminated structure including a multilayer film layer having magnetization orientation that is stable in the perpendicular direction can be more surely formed.

### Advantageous Effects of Invention

As described above, the present invention makes it possible to surely form a multiferroic laminated structure including a multilayer film layer having magnetization orientation that is stable in the perpendicular direction. Further, application of the laminated structure to a switching element makes it possible to easily control the magnetization orientation through voltage application.

### BRIEF DESCRIPTION OF THE SEVERAL VIEWS OF THE DRAWINGS

FIG. 1 is a diagram schematically showing a configuration of a laminated structure according to an embodiment of the present invention.

FIG. 2 is a flow chart schematically showing a method for manufacturing a laminated structure according to an embodiment of the present invention.

FIG. 3 is a diagram schematically showing a switching element including a laminated structure according to an embodiment of the present invention.

FIG. 4A through FIG. 4C is a schematic diagram showing an application example of a magnetic device comprising a switching element according to an embodiment of the present invention.

FIG. 5 is a characteristic diagram showing an XRD pattern of an example of a laminated structure according to an embodiment of the present invention.

FIG. 6 is a diagram showing a RHEED pattern of a Cu layer on the uppermost face side of an example of a laminated structure according to an embodiment of the present invention.

FIG. 7 is a diagram showing the temperature dependence of magnetization with respect to an out-of-plane magnetic field and an in-plane magnetic field of an example of a laminated structure according to an embodiment of the present invention.

FIG. 8 is a diagram schematically showing an example of a switching element including a laminated structure according to an embodiment of the present invention.

FIG. 9A shows an out-of-plane magnetization curve of an example of a switching element including a laminated structure according to an embodiment of the present invention at room temperature in the absence of voltage being applied, and FIG. 9B shows an out-of-plane magnetization curve of the switching element at room temperature in the presence of voltage being applied.

FIG. 10A shows an in-plane magnetization curve of an example of a switching element including a laminated structure according to an embodiment of the present invention at room temperature in the absence of voltage being applied, and FIG. 10B shows an in-plane magnetization curve of the switching element at room temperature in the presence of voltage being applied.

FIG. 11 is a diagram showing changes in out-of-plane magnetization of an example of a switching element including a laminated structure according to an embodiment of the present invention along with voltage application.

FIG. 12 is a diagram showing changes in out-of-plane magnetization in a case where control of reversal of magnetization between upward and downward out-of-plane directions by voltage has been performed on an example of a switching element including a laminated structure according to an embodiment of the present invention.

### DETAILED DESCRIPTION OF THE INVENTION

Preferred embodiments of the present invention will be described in detail below. It is to be noted that the present embodiments described below are not intended to unduly limit the scope of the present invention as specified in the claims, and what is described in the present embodiments is not always all indispensable as the solving means of the present invention.

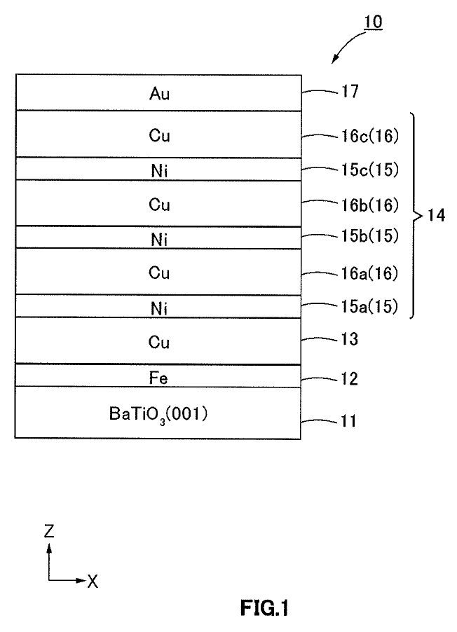

First, a configuration of a laminated structure according to an embodiment of the present invention is described with reference to the drawings. FIG. 1 is a diagram schematically showing a configuration of a laminated structure according to an embodiment of the present invention.

A laminated structure 10 according to an embodiment of the present invention is a multiferroic crystalline body having both ferroelectricity and ferromagnetism, and has magnetization orientation that is stable in a perpendicular direction. That is, the laminated structure 10 according to the present embodiment is one achieved as a ferromagnetic/non-magnetic multilayer film/ferroelectric substance multiferroic structure having perpendicular magnetic anisotropy by providing a ferromagnetic/non-magnetic multilayer film on top of a ferroelectric substance by epitaxially growing the ferromagnetic/non-magnetic multilayer film.

As shown in FIG. 1, the laminated structure 10 according to the present embodiment includes a ferroelectric layer 11, a foundation layer 12, an intermediate layer 13, a ferromagnetic/non-magnetic multilayer film layer 14 composed of ferromagnetic layers 15 and non-magnetic layers 16, and a metal film layer 17. The ferroelectric layer 11 serves as a substrate. The foundation layer 12, the intermediate layer 13, the ferromagnetic/non-magnetic multilayer film layer 14, and the metal film layer 17 are laminated on top of the ferroelectric layer 11 by epitaxially growing their respective components. That is, the present embodiment is configured such that the ferromagnetic/non-magnetic multilayer film layer 14 is provided on top of the ferroelectric layer 11 with the foundation layer 12 and the intermediate layer 13 sandwiched therebetween. Moreover, the metal film layer 17, which is made of gold Au, is provided on the top side, i.e. the uppermost layer side, of the multilayer film layer 14 in order to prevent oxidation of the multilayer film layer 14.

In the present embodiment, barium titanate BaTiO₃ having (001) orientation is used as a ferroelectric substance that constitutes the ferroelectric layer 11, which serves as a substrate for the laminated structure 10. Further, as shown in FIG. 1, the ferromagnetic/non-magnetic multilayer film layer 14 is constituted by alternately laminating the ferromagnetic layers 15 and the non-magnetic layers 16 in three cycles. The ferromagnetic layers 15 are composed mainly of nickel Ni, which is a ferromagnetic substance, and the non-magnetic layers 16 are composed mainly of copper Cu, which is a non-magnetic substance. In the present embodiment, the multilayer film layer 14 is constituted by alternately laminating ferromagnetic layers 15a, 15b, and 15c and non-magnetic layers 16a, 16b, and 16c in three cycles. However, for flat interfaces between the ferromagnetic layers 15 and the non-magnetic layers 16, whose thicknesses are in nanometers, the multilayer film layer 14 needs to be constituted by alternately laminating the ferromagnetic layers 15 and the non-magnetic layers 16 in at least three cycles.

Further, in the present embodiment, the foundation layer 12, which is laminated on a surface of the ferroelectric layer 11, is composed mainly of a metal having a good lattice-matching property with at least barium titanate. Specifically, iron Fe is used as a metal that constitutes the foundation layer 12. Moreover, the intermediate layer 13 is provided between the foundation layer 12 and the multilayer film layer 14. The intermediate layer 13 is made of copper Cu, which is the same non-magnetic substance as that of which the non-magnetic layers 16 of the Ni/Cu ferromagnetic/non-magnetic multilayer film layer 14 are made. It should be noted that as the structure of the ferromagnetic/non-magnetic multilayer film layer 14, a perpendicular magnetization film such as Co/Ni or Co/Pt as well as Ni/Cu is considered to be applicable, although it is preferable that the coercivity not be high.

Further, in order for the laminated structure 10 to be a multiferroic crystalline body having magnetization orientation that is stable in the perpendicular direction, it is necessary that the thickness of each of the layers that are laminated on top of the ferroelectric layer 11 take on a small value in nanometers. In the laminated structure 10 according to an embodiment of the present invention, for example, the foundation layer 12 has a thickness of 1 nm, the intermediate layer 13 and the non-magnetic layers 16 each have a thickness of 9 nm, the ferromagnetic layers 15 each have a thickness of 2 nm, and the metal film layer 17 has a thickness of 5 nm. Since it is necessary to increase surface strains of the ferromagnetic layers 15 for stable magnetization orientation in the perpendicular direction, it is necessary that the non-magnetic layers 16 be larger in thickness than the ferromagnetic layers 15. However, since an increase in the distance between the ferromagnetic layers 15 and the ferroelectric layer 11 makes it hard to transmit a piezoelectric strain of the ferroelectric layer 11 to the multilayer film layer 14 and therefore makes it difficult to control the magnetization orientation with voltage, it is preferable that the thickness of each of the non-magnetic layers 16 not be equal to or larger than 10 nm.

In the present embodiment, the foundation layer 12 is provided as a buffer layer that has a function of alleviating the lattice mismatch between barium titanate BaTiO₃ constituting the ferroelectric layer 11 and copper Cu constituting the intermediate layer 13. Since the difference in lattice constant between barium titanate BaTiO₃ and copper Cu is great, alternately laminating copper Cu and nickel Ni directly on top of the ferroelectric layer 11, which is made of barium titanate, prevents epitaxial junctions at interfaces of the multilayer film layer 14 and therefore prevents the magnetization orientation of the multilayer film layer 14 from being aligned in the perpendicular direction. That is, alleviation of the lattice mismatch is needed for epitaxial growth of copper Cu and nickel Ni constituting the multilayer film layer 14.

For this reason, in the present embodiment, the foundation layer 12, which serves as a buffer layer in the shape of a thin film composed mainly of iron Fe, is sandwiched between the ferroelectric layer 11 and the intermediate layer 13. Laminating the foundation layer 12, which is made of iron, on top of the ferroelectric layer 11, which is made of barium titanate, causes a lattice of iron to be deposited on top of a lattice of barium titanate with a 45-degree rotation. That is, the lattice of iron matches the barium titanate in diagonal direction. Since the lattice constant of iron is 0.286 nm, the diagonal length of the lattice is 0.403 nm, which substantially matches the lattice constant of barium titanate (a=b=0.3992 nm, c=0.4038 nm).

Since iron is thus a metal that has good a lattice-matching property with barium titanate, iron forms the foundation layer 12 by epitaxially growing on top of the ferroelectric layer 11, which is made of barium titanate. That is, sandwiching the foundation layer 12, which is made of iron Fe, as a buffer layer causes a part of the foundation layer 12 that is close to the ferroelectric layer 11 to form a film by lattice-matching barium titanate. Meanwhile, a part of the foundation layer 12 that is close to the intermediate layer 13 forms a film by lattice-matching copper Cu. Moreover, the foundation layer 12, which serves as a buffer layer, comes to alleviate the lattice mismatch between barium titanate constituting the ferroelectric layer 11 and copper constituting the intermediate layer 13.

That is, by providing the foundation layer 12, which is in the shape of a thin film made of iron Fe, as a buffer layer on top of the ferroelectric layer 11, the lattice mismatch between barium titanate BaTiO₃ constituting the ferroelectric layer 11 and copper Cu constituting the intermediate layer 13 is alleviated, as iron has a good lattice-matching property with barium titanate constituting the ferroelectric layer 11. For this reason, the multilayer film layer 14 is laminated in a stable state on top of the ferroelectric layer 11, which is made of barium titanate, and a lattice of nickel Ni constituting the ferromagnetic layers 15 is expanded by a lattice of copper Cu constituting the non-magnetic layers 16. This makes it possible to stabilize the magnetization orientation of the multilayer film layer 14 in the perpendicular direction.

Further, in the present embodiment, the intermediate layer 13, which is composed mainly of the same non-magnetic substance as that of which the non-magnetic layers 16 of the multilayer film layer 14 are made, is provided between the foundation layer 12 and the multilayer film layer 14. That is, after the intermediate layer 13 has been laminated on a surface of the foundation layer 12, the multilayer film layer 14 is laminated on top of intermediate layer 13.

As mentioned above, in the present embodiment, the foundation layer 12, which is made of iron Fe, i.e. a ferroelectric substance, is provided between the ferroelectric layer 11 and the multilayer film layer 14. However, if the intermediate layer 13 is not provided, the foundation layer 12 and the ferromagnetic layer 15a, which is provided on the bottom side of the multilayer film layer 14, will be in direct contact with each other. Such an overlap between the foundation layer 12 and the ferromagnetic layer 15a, which are constituted by ferromagnetic substances, leads to an increase in thickness of the ferromagnetic portion, thus making it hard for the magnetization orientation of the multilayer film layer 14 to face in the perpendicular direction. Hence, the intermediate layer 13 is provided so that, in order for the multilayer film layer 14 to have stable perpendicular magnetization orientation, the ferromagnetic layer 15a, which is closest to the ferroelectric layer 11 among the ferromagnetic layers 15 of the multilayer film layer 14, and the foundation layer 12, which is similarly made of a ferromagnetic substance, are not in direct contact with each other.

Thus, in the present embodiment, the multiferroic laminated structure 10 is formed by epitaxially growing the ferromagnetic/non-magnetic multilayer film layer 14 on top of the ferroelectric layer 11 with the foundation layer 12 and the intermediate layer 13 sandwiched therebetween. Such a multiferroic laminated structure 10 causes the lattice of nickel Ni constituting the ferromagnetic layers 15 to be expanded by the lattice of copper Cu constituting the non-magnetic layers 16. This makes it possible to surely form a multiferroic laminated structure 10 including a multilayer film 14 having magnetization orientation that is stable in the perpendicular direction.

Further, as a result of diligent studies to attain the aforementioned object of the present invention, the inventors of the present invention found that application of voltage to a magnetic switching element to which a laminated structure 10 according to the present embodiment is applied makes it possible to easily switch the magnetization orientation of the multilayer film layer 14 from the perpendicular direction to an in-plane direction. For this reason, application of a laminated structure 10 according to the present embodiment to a magnetic switching element enables the turning on and turning off of a stray field of the multilayer film layer 14 by voltage.

Moreover, application of such a switching element to various magnetic devices such as magnetic heads and MRAM enables magnetic high-speed writing and reading, thus making it possible to improve the performance of the magnetic devices. It should be noted that an example of application of a laminated structure 10 according to the present embodiment to a switching element, details of a magnetic device to which such a switching element is applied, and an example in which a laminated structure 10 according to the present embodiment is applied to a magnetic switching element will be described later.

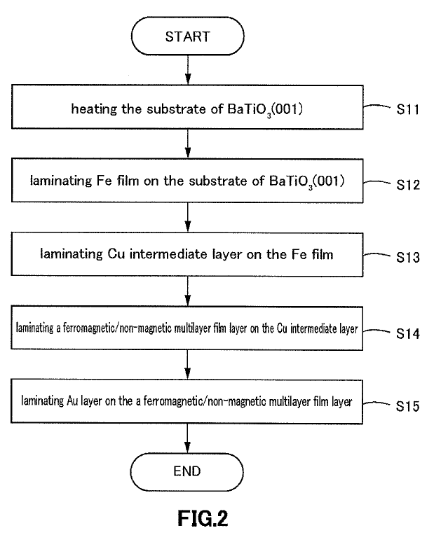

Next, a method for manufacturing a laminated structure according to an embodiment of the present invention is described with reference to the drawings. FIG. 2 is a flow chart schematically showing a method for manufacturing a laminated structure according to an embodiment of the present invention.

A method for manufacturing a laminated structure according to an embodiment of the present invention makes it possible that, as a multiferroic laminated structure having both ferroelectricity and ferromagnetism, one including a multilayer film layer having magnetization orientation that is stable in the perpendicular direction is surely formed by epitaxial growth. That is, in the method for manufacturing a laminated structure 10 according to the present embodiment, a crystalline body of a ferromagnetic/non-magnetic multilayer film/ferroelectric substance multiferroic structure having perpendicular magnetization orientation (perpendicular magnetic anisotropy) is formed by an epitaxial junction of a ferromagnetic/non-magnetic multilayer film layer 14 on top of a ferroelectric layer 11 as the laminated structure 10.

In manufacturing a laminated structure 10 according to an embodiment of the present invention, first, a ferroelectric layer 11 that is to serve as a substrate for the laminated structure 10 is treated with heat at 700° C. under a vacuum condition (heat treatment step S11). In the present embodiment, as mentioned above, barium titanate BaTiO₃ is used as a ferroelectric substance that constitutes the ferroelectric layer 11, which is to serve as the substrate.

Next, a foundation layer 12 composed mainly of a metal having a good lattice-matching property with barium titanate BaTiO₃ serving as a ferroelectric substance is laminated on the top face side, i.e. a surface, of the ferroelectric layer 11 by epitaxial growth (foundation layer lamination step S12). In the present embodiment, iron Fe is used as a metal that constitutes the foundation layer 12. After that, an intermediate layer 13 composed mainly of a non-magnetic substance is laminated on the top face side, i.e. a surface, of the foundation layer 12 by epitaxial growth (intermediate layer lamination step S13). In the present embodiment, copper Cu is used as a non-magnetic substance that constitutes the intermediate layer 13.

Once the intermediate layer 13 is laminated, a ferromagnetic/non-magnetic multilayer film layer 14 is then laminated on the top face side, i.e. a surface, of the intermediate layer 13 (multilayer film layer lamination step S14). In the present embodiment, in the multilayer film layer lamination step S14, first, a ferromagnetic layer 15 constituted by nickel Ni as a ferromagnetic substance is laminated on the top face side, i.e. a surface, of the intermediate layer 13 by epitaxial growth. Next, a non-magnetic layer 16 composed mainly of copper Cu as a non-magnetic substance is laminated on the top face side, i.e. a surface, of the ferromagnetic layer 15 by epitaxial growth.

Then, the lamination of a ferromagnetic layer 15 and a non-magnetic layer 16 is repeated twice, whereby the multilayer film layer 14 is formed. That is, in the present embodiment, the multilayer film layer 14 is constituted by alternately laminating the ferromagnetic layers 15, which are composed mainly of a ferromagnetic substance, and the non-magnetic layers 16, which are composed mainly of a non-magnetic substance, in at least three cycles.

After that, on the top face side, i.e. a surface, of the non-magnetic layer 16c provided on the uppermost side of the ferromagnetic/non-magnetic multilayer film layer 14, a metal film layer 17 composed mainly of gold Au is laminated by epitaxial growth in order to prevent oxidation of the multilayer film layer 14 (metal film layer lamination step S15). Thus, in the present embodiment, a multiferroic laminated structure 10 including a multilayer film layer 14 having magnetization orientation that is stable in the perpendicular direction can be easily formed by epitaxial growth. That is, an epitaxial junction of the ferromagnetic/non-magnetic multilayer film layer 14 with the ferroelectric layer 11 with the foundation layer 12 and the intermediate layer 13 sandwiched therebetween makes it possible to surely form a crystalline body of a ferromagnetic/non-magnetic multilayer film/ferroelectric substance multiferroic structure having stable perpendicular magnetization orientation.

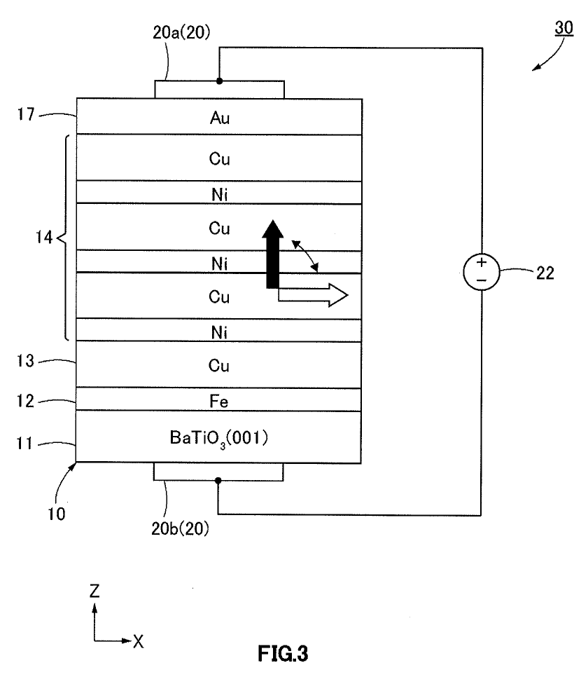

Next, a configuration of a switching element including a laminated structure according to an embodiment of the present invention is described with reference to the drawings. FIG. 3 is a diagram schematically showing a switching element including a laminated structure according to an embodiment of the present invention.

A switching element 30 according to an embodiment of the present invention is a magnetic switching element that can be turned on and off by application of voltage. In the present embodiment, as shown in FIG. 3, the switching element 30 includes electrodes 20 (20a, 20b) connected to a power supply 22 such as a voltage supply and a laminated structure 10 according to the present embodiment provided between these electrodes 20a and 20b.

As described above, the laminated structure 10 is a multiferroic crystalline body of a structure having both ferroelectricity and ferromagnetism, and has magnetization orientation that is stable in the perpendicular direction. As shown in FIG. 3, the laminated structure 10 includes a ferroelectric layer 11 composed mainly of barium titanate BaTiO₃ (001), a foundation layer 12 made of iron Fe, an intermediate layer 13, made of copper Cu, a ferromagnetic/non-magnetic multilayer film layer 14 composed of nickel Ni and copper Cu, and a metal film layer 17 made of gold Au. The ferroelectric layer 11 serves as a substrate. The foundation layer 12, the intermediate layer 13, the ferromagnetic/non-magnetic multilayer film layer 14, and the metal film layer 17 are epitaxially joined on top of the ferroelectric layer 11.

As mentioned above, the laminated structure 10 is a multiferroic crystalline body having both ferroelectricity and ferromagnetism, and thereby has magnetization orientation that is stable in the perpendicular direction. Further, application of voltage to the switching element 30 including the laminated structure 10 according to the present embodiment makes it possible to switch the magnetization orientation of the multilayer film layer 14 from the perpendicular direction to the in-plane direction. Furthermore, application of the laminated structure 10 to the switching element 30 makes it possible to control the turning on and turning off of a stray field of the multilayer film layer 14 with voltage. The term “perpendicular direction” as used herein in association with magnetization orientation means a direction substantially perpendicular to a surface of each of the layers of the laminated structure 10 (i.e. a direction of the Z axis shown in FIG. 3), and the term “in-plane direction” means a direction substantially parallel to each of the interfaces of the multilayer film layer 14 of the laminated structure 10 (i.e. a direction of the X axis shown in FIG. 3).

Thus far, since the magnetization orientation (magnetic anisotropy) of a ferromagnetic/non-magnetic multilayer film is closely associated with an interface strain of the multilayer film, it has been thought that a switching element capable of switching between a perpendicular magnetization orientation state and an in-plane magnetization orientation state can be configured, provided the interface strain can be controlled from outside. Meanwhile, since a ferroelectric substance such as barium titanate exhibits a piezoelectric effect, it has been thought that a piezoelectric strain of a ferroelectric substance can be highly efficiently transmitted to a ferromagnetic/non-magnetic multilayer film by joining the ferroelectric substance and the ferromagnetic/non-magnetic multilayer film and utilizing the piezoelectric strain. Therefore, the switching element 30 according to an embodiment of the present invention has been conceived of.

Application of the laminated structure 10 according to the present embodiment to the switching element 30 makes it possible to surely form a switching element capable of controlling the switching of the magnetization orientation of the multilayer film layer 14 through voltage application. That is, application of voltage to the multiferroic laminated structure 10 makes it possible to transmit, to the multilayer film layer 14, a piezoelectric strain of barium titanate BaTiO₃ serving as a ferroelectric substance that constitutes the ferroelectric layer 11, thus making it possible to switch the magnetization orientation between the perpendicular magnetization state and the in-plane magnetization state.

In other words, application of voltage from the power supply 22 in the absence of a magnetic field achieves the formation of a switching element 30 that makes it possible to convert the magnetization orientation between the perpendicular magnetization state and the in-plane magnetization state. This makes it possible to switch between the perpendicular magnetization orientation state and the in-plane magnetization orientation state with voltage alone without using electric currents as has been done conventionally, thus achieving a power saving of a magnetic device including the switching element 30. It should be noted that details of an example of control of the magnetization orientation of the multilayer film layer 14 along with voltage application will be described later.

Further, a conventional perpendicular magnetic modulation element structure of a voltage application type cannot switch between perpendicular and in-plane magnetization orientation with voltage alone, although it is capable of changing coercivity with voltage. Even in so doing, it requires a high electric field in megaunits (MV/cm) or larger. On the other hand, the present embodiment can achieve a switching element 30 capable of completely controlling perpendicular and in-plane magnetization orientation with an electric field of 10 kV/cm, which is smaller than the conventionally required electric field by two or more orders of magnitude.

Furthermore, in a conventional technique for controlling the voltage of a ultra-thin film of perpendicular magnetization orientation, it has been difficult to manufacture a magnetic device utilizing a stray field in a perpendicular magnetization state, as the magnetic film used is so extremely thin as to have a film thickness of approximately 1 nm. On the other hand, a switching element 30 to which a laminated structure 10 according to the present embodiment is applied can generate a higher stray field from the ferromagnetic substance than a conventional switching element, as the switching element 30 uses the ferromagnetic substance/non-magnetic substance multilayer film layer 14 and the plurality of ferromagnetic layers 15 and the plurality of non-magnetic layers 16 are alternately laminated. For this reason, when the switching element 30 according to the present embodiment is applied to a magnetic device such as a spin transistor, such a stray field can be utilized to make it easy to control the spin direction.

Further, concomitant use of voltage and a magnetic field enables the switching element 30 to which a laminated structure 10 according to the present embodiment is applied to not only control the magnetization orientation of the multilayer film layer 14 in the perpendicular and in-plane directions but also make a 180-degree reversal of perpendicular magnetization. That is, when a magnetic field whose strength continuously varies in a predetermined direction is further applied to the multilayer film layer 14 and the strength of the magnetic field changes from 0 to a predetermined negative minute value, application of voltage from the power supply 22 makes it possible to switch the magnetization orientation of the multilayer film layer 14 between an upward perpendicular direction and a downward perpendicular direction. In other words, the perpendicular magnetization orientation of the multilayer film layer 14 including the ferromagnetic layers 15 can be reversed 180 degrees by voltage application. It should be noted that details of an example of control of reversal of the magnetization orientation of the multilayer film layer 14 by voltage application in a magnetic field environment will be described later.

Furthermore, in the present embodiment, the magnetization orientation of the multilayer film layer 14 of the laminated structure 10 can be switched by changing an environmental temperature at which the laminated structure 10 to a predetermined temperature. That is, the magnetization orientation of the laminated structure 10 that is applied to the switching element 30 is switched between the perpendicular direction and the in-plane direction at the predetermined temperature.

Specifically, the magnetization orientation of the multilayer film layer 14 is switched from the perpendicular direction to the in-plane direction by lowering the environmental temperature at which the laminated structure 10 is provided from room temperature to a temperature of around 190 K. This is considered to be attributed to a lattice strain entailed by the structural phase transition at 190 K of barium titanate BaTiO₃ constituting the ferroelectric layer 11, which serves as a substrate for the laminated structure 10. Thus, application of the laminated structure 10 according to the present embodiment to the switching element 30 makes it possible to switch the magnetization orientation of the multilayer film layer 14 between the perpendicular direction and the in-plane direction by controlling the temperature. It should be noted that details of an example of control of the magnetization orientation of the multilayer film layer 14 along with temperature change will be described later.

As described above, application to the switching element 30 of a multiferroic laminated structure 10 including a multilayer film layer 14 having magnetization orientation that is stable in the perpendicular direction makes it possible to easily control the magnetization orientation of the multilayer film layer 14 through voltage application. That is, utilization of a laminated structure 10 according to the present embodiment makes it possible to perform magnetization orientation control with voltage alone, although such magnetization orientation control has hitherto been performed by electric currents.

For this reason, the switching element 30 including a laminated structure 10 according to the present embodiment can be applied to various magnetic devices. For example, in a spin electronics device such as a spin transistor or a spin light-emitting diode, a laminated structure 10 or a switching element 30 according to the present embodiment can be applied as a ferromagnetic electrode capable of voltage control of magnetization orientation. Further, since a stray field of the multilayer film layer 14 can be controlled by voltage, the switching element 30 including a laminated structure 10 according to the present embodiment can be applied to magnetic recording elements such as GMR elements, high-density HD TMR elements, magnetic heads, and spin FETs, as well as MRAM. Furthermore, the switching element 30 including a laminated structure 10 according to the present embodiment can also be applied to a micromotor that is driven by controlling a stray field with voltage. Further, application of the switching element 30 including a laminated structure 10 according to the present embodiment to various magnetic devices makes it possible to control magnetization orientation with voltage alone without using electric currents, thus making it possible to remarkably reduce the consumption of power during operation of these magnetic devices.

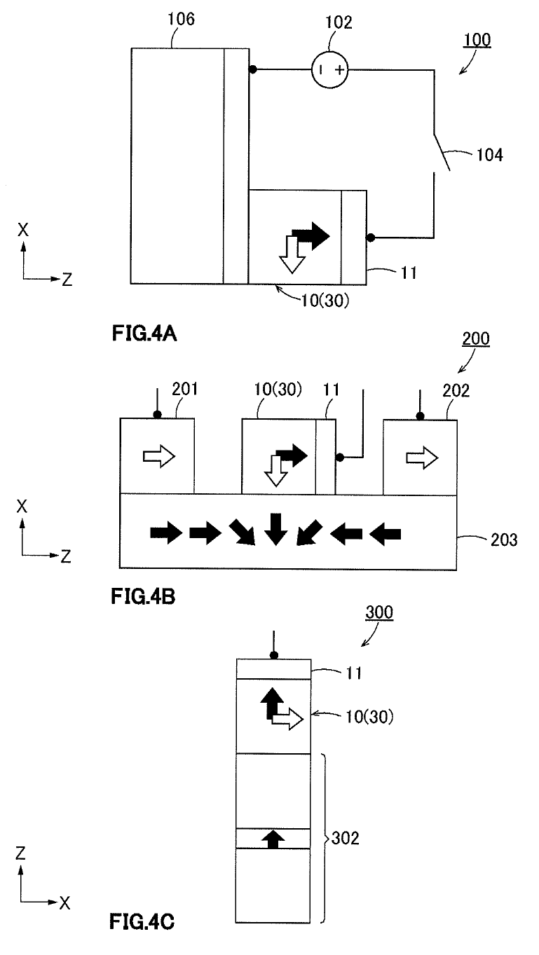

Next, examples of application to a magnetic device of a switching element including a laminated structure according to an embodiment of the present invention are described with reference to the drawings. FIG. 4A is a diagram schematically showing a configuration of an example of application of a switching element according to an embodiment of the present invention to a magnetic head. FIG. 4B is a diagram schematically showing a configuration of an example of application of a switching element according to an embodiment of the present invention to a spin transistor. FIG. 4C is a diagram schematically showing a configuration of an example of application of a switching element according to an embodiment of the present invention to a polarization control light-emitting element.

As shown in FIG. 4A, since the application to a magnetic head 100 of a switching element 30 including a laminated structure 10 according to an embodiment of the present invention brings the laminated structure 10 into a electric-field-free state when no voltage is applied from a power supply 102, the magnetization orientation is in the perpendicular direction (i.e. a direction of the Z axis shown in FIG. 4A). On the other hand, when voltage is applied to the laminated structure 10 with input to a switch 104, the magnetization orientation switches from the perpendicular direction to the in-plane direction (i.e. a direction of the X axis shown in FIG. 4A).

Thus, the switching of the magnetization orientation from the perpendicular direction to the in-plane direction allows writing to be performed on a magnetic medium (not illustrated) by a stray field from the multilayer film layer 14 (see FIG. 3) of the laminated structure 10. That is, a writing operation with use of the magnetic head 100 can be controlled by controlling the stray field of the multilayer film layer 14 with voltage. It should be noted that, in the present embodiment, the control of the magnetization orientation by voltage application enables a reading operation based on a magnetostrictive effect and a piezoelectric effect, as well as the writing operation with use of the magnetic head 100.

Further, as shown in FIG. 4B, since the application of the switching element 30 including a laminated structure 10 according to an embodiment of the present invention to a spin transistor 200 provided with magnetic electrodes 201 and 202 brings the laminated structure 10 into a field-free state when no voltage is applied from a power supply (not illustrated), the magnetization orientation is in the perpendicular direction (i.e. a direction of the Z axis shown in FIG. 4B). On the other hand, when voltage is applied to the laminated structure 10, the magnetization orientation switches from the perpendicular direction to the in-plane direction (i.e. a direction of the X axis shown in FIG. 4B). Thus, the switching of the magnetization orientation from the perpendicular direction to the in-plane direction allows the spin direction of a semiconductor channel layer 203 to be controlled by a stray field from the multilayer film layer 14 (see FIG. 3) of the laminated structure 10.

Furthermore, as shown in FIG. 4C, since the application of the switching element 30 including a laminated structure 10 according to an embodiment of the present invention to a polarization control light-emitting element 300 provided with a semiconductor quantum well 302 brings the laminated structure 10 into a field-free state when no voltage is applied from a power supply (not illustrated), the magnetization orientation is in the perpendicular direction (i.e. a direction of the Z axis shown in FIG. 4C). On the other hand, when voltage is applied to the laminated structure 10, the magnetization orientation switches from the perpendicular direction to the in-plane direction (i.e. a direction of the X axis shown in FIG. 4C). Thus, the switching of the magnetization orientation from the perpendicular direction to the in-plane direction makes it possible to control the polarization of the polarization control light-emitting element 300.

Thus, the application of the switching element 30 including a laminated structure 10 according to an embodiment of the present invention to the various magnetic devices 100, 200, and 300 makes it possible, for example, to perform a stable writing operation on the magnetic device 100, control the spin direction of the magnetic device 200, and control the polarization of the magnetic device 300. That is, the switching element 30 including a laminated structure 10 according to an embodiment of the present invention can expand its range of applications, as it can impart perpendicular magnetic anisotropy through voltage application to magnetic devices that are hard to apply with the conventional in-plane magnetization control alone.

Further, application of the switching element 30 including a laminated structure 10 according to the present embodiment to various magnetic devices makes it possible to control magnetization orientation with voltage alone without using electric currents, thus making it possible to remarkably reduce the consumption of power during operation of these magnetic devices. Thus, application to a magnetic device of a switching element 30 capable of controlling the switching of the magnetization orientation through voltage application makes it possible to improve the performance of the magnetic device.

### Examples

The following describes an example of a laminated structure according to an embodiment of the present invention. A laminated structure serving as an example of the present embodiment is a ferromagnetic/non-magnetic multilayer film/ferroelectric substance multiferroic structure, and is constituted by [Cu/Ni] multilayer film/Cu intermediate layer/Fe foundation layer/BaTiO₃ single crystal. In the present example, the Fe foundation layer and the Cu intermediate layer are inserted between the multilayer film with five cycles of [Cu/Ni] and BaTiO₃, resulting in a structure in which the [Cu/Ni] multilayer film is epitaxially grown on top of BaTiO₃. This makes it possible to efficiently transmit a piezoelectric strain of BaTiO₃ via junction interfaces of the [Cu/Ni] multilayer film.

In a method for manufacturing a multiferroic laminated structure of the present example, first, a single crystal BaTiO₃ (001) having an in-plane-perpendicular dielectric multidomain state is treated with heat at 700° C. for one hour in vacuum with an ultra-high vacuum MBE apparatus, and then an Fe thin film having a film thickness of 1 nm is epitaxially grown on top of the BaTiO₃ substrate at a substrate temperature of 300° C. After that, a Cu layer having a film thickness of 9 nm is epitaxially grown, and a multilayer film with five cycles of [Cu/Ni] is produced. The multilayer film has a Cu film thickness of 9 nm and a Ni film thickness of 2 nm. Further, for the purpose of preventing oxidation of the multilayer film, a Au film having a film thickness of 5 nm is epitaxially grown to make a ferromagnetic/non-magnetic multilayer film/ferroelectric substance multiferroic structure.

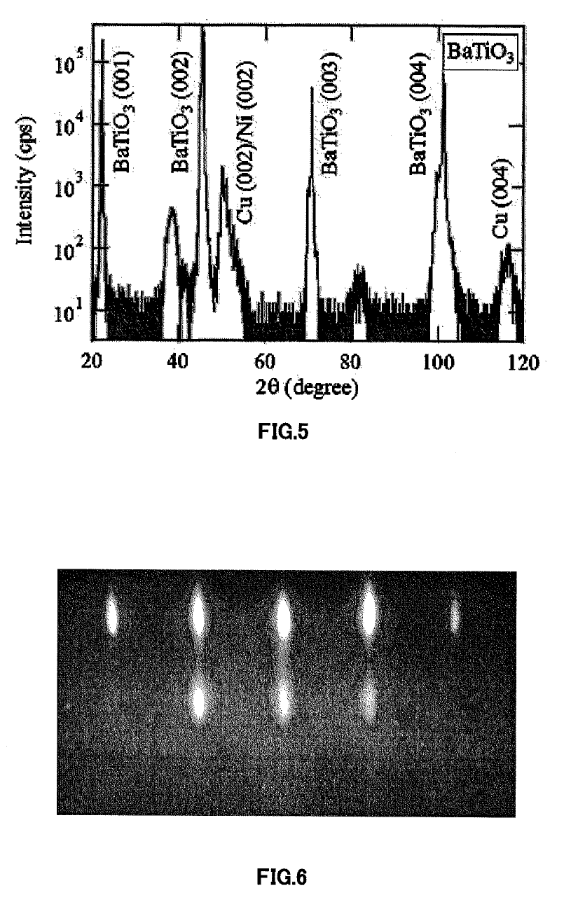

A configuration of the laminated structure of the present example described above is described with reference to the drawings. FIG. 5 is a characteristic diagram showing an XRD pattern of an example of a laminated structure according to an embodiment of the present invention. FIG. 6 is a diagram showing an RHEED pattern of a Cu layer on the uppermost face side of an example of a laminated structure according to an embodiment of the present invention.

As shown in FIG. 5, the XRD pattern of the laminated structure of the present example shows that both barium titanate BaTiO₃ serving as a ferroelectric substance and the Cu/Ni multilayer film have their crystals facing in the (001) direction, i.e. a direction perpendicular to the interfaces of the multilayer film (i.e. a direction of the Z axis shown in FIG. 1). Further, the appearance of fringe structures at the peaks of barium titanate BaTiO₃ and the Cu/Ni multilayer film shows that the interfaces of the Cu/Ni multilayer film laminated on top of barium titanate BaTiO₃ are flatly and stably laminated at the atomic level. That is, the present example demonstrates that a laminated structure having high-quality crystallinity is formed by the method for manufacturing a laminated structure according to an embodiment of the present invention.

Further, as shown in FIG. 6, the RHEED pattern of the Cu layer on a surface on the uppermost face side, i.e. the top face side, of an example of a laminated structure according to an embodiment of the present invention shows that streaky lines of white light appear at predetermined intervals. This shows that the surface of the Cu layer on the uppermost face side of the laminated structure of the present example is flat. That is, the present example demonstrates that since the interfaces of the multilayer film of the laminated structure are flatly formed by the method for manufacturing a laminated structure according to an embodiment of the present invention, the manufacture of a laminated structure by stable epitaxial growth is possible.

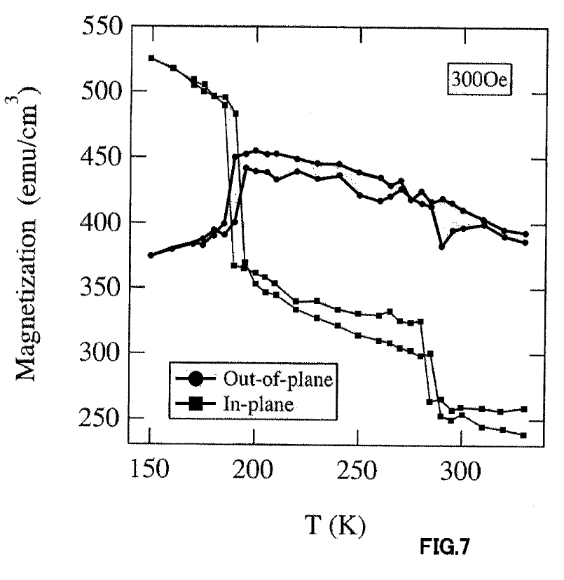

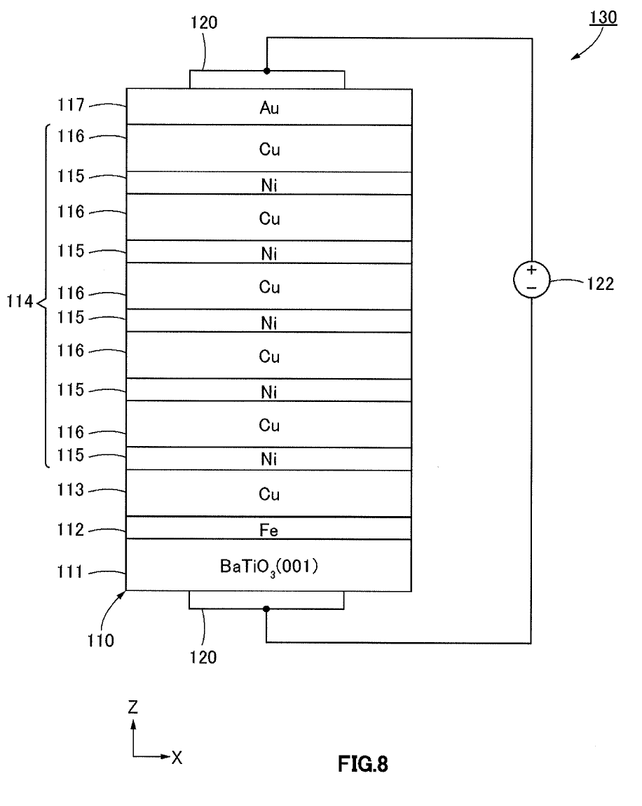

Next, the temperature dependence of magnetization with respect to an out-of-plane magnetic field and an in-plane magnetic field of the laminated structure of the present example described above is described with reference to the drawings. FIG. 7 is a diagram showing the temperature dependence of magnetization with respect to an out-of-plane magnetic field and an in-plane magnetic field of an example of a laminated structure according to an embodiment of the present invention. It should be noted that, in FIG. 7, the data plot of black circular dots represents the temperature dependence of magnetization with respect to an out-of-plane magnetic field (perpendicular magnetic field), and the data plot of black quadrangular dots represents the temperature dependence of magnetization with respect to an in-plane magnetic field.

As shown in FIG. 7, the ferromagnetic/non-magnetic multilayer film/ferroelectric substance multiferroic laminated structure of the present example is found to be in an out-of-plane magnetization orientation, as it gives greater magnetization when an out-of-plane magnetic field is applied at room temperature than when an in-plane magnetic field is applied. Cooling this multiferroic laminated structure causes discontinuous hops of magnetization to appear at around 280 K. Further, similar hops are observed at around 180 K, too. These hops of magnetization are attributed to interface strains entailed by structural phase transitions from the tetragonal phase to the orthorhombic phase and from the orthorhombic phase to the rhombohedral phase of BaTiO₃.

Furthermore, unlike at room temperature, in-plane magnetization is greater than out-of-plane magnetization at 180 K. This shows that the interface strains entailed by the structural phase transitions of BaTiO₃ effected magnetization orientation switching from perpendicular magnetization to in-plane magnetization. This shows that magnetization orientation can be controlled to be perpendicular or in-plane according to temperature change. That is, it is demonstrated that the magnetization orientation of the multilayer film layer can be switched between the perpendicular direction and the in-plane direction by controlling the environmental temperature at which the laminated structure is provided.

Next, an example of a switching element including a laminated structure according to an embodiment of the present invention is described with reference to the drawings. FIG. 8 is a diagram schematically showing an example of a switching element including a laminated structure according to an embodiment of the present invention.

As shown in FIG. 8, a switching element 130 of the present example includes a multiferroic laminated structure 110 constituted by [Cu/Ni] multilayer film/Cu intermediate layer/Fe foundation layer/BaTiO₃ single crystal. In the present example, the Fe foundation layer 112 and the Cu intermediate layer 113 are inserted between the multilayer film 114 with five cycles of [Cu/Ni] and BaTiO₃, resulting in a structure in which the [Cu/Ni] multilayer film 114 is epitaxially grown on top of the ferroelectric layer 111 made of BaTiO₃. Moreover, a magnetic switching element of a voltage control type is made by attaching electrodes 120 to an upper Au layer 117 of the ferromagnetic/non-magnetic multilayer film/ferroelectric substance multiferroic laminated structure 110 and a back face portion of the BaTiO₃ layer 111, respectively.

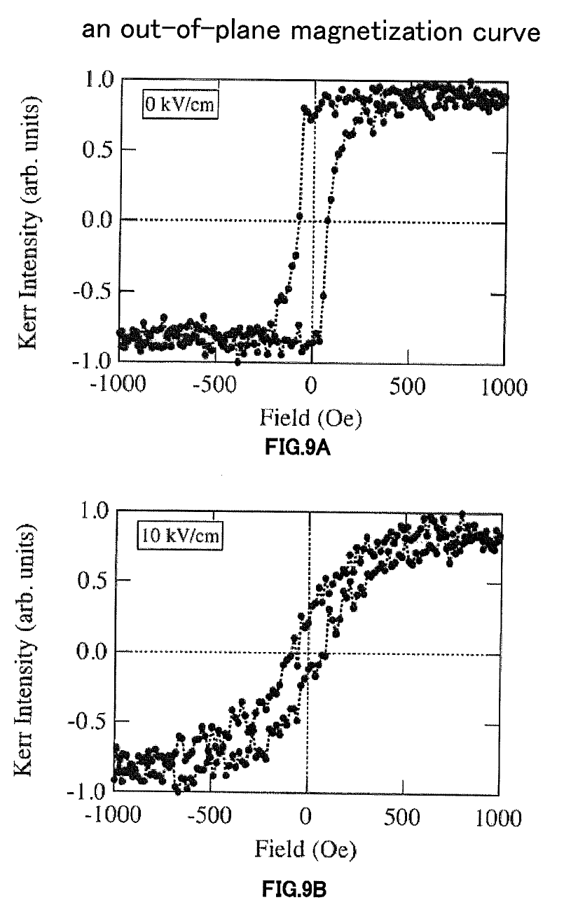

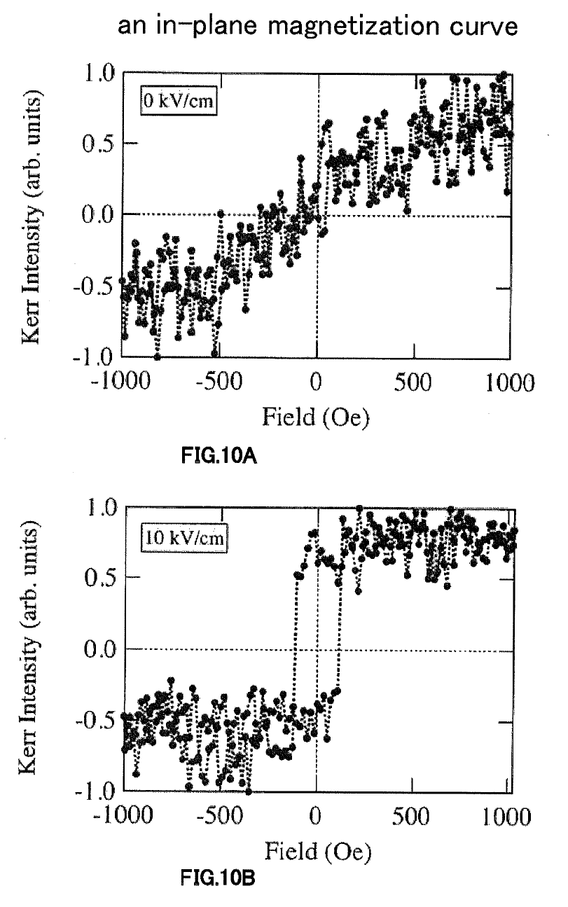

The control of magnetization orientation by application of voltage to the switching element 130 of the present example is described with reference to the drawings. FIG. 9A shows an out-of-plane magnetization curve of an example of a switching element including a laminated structure according to an embodiment of the present invention at room temperature in the absence of voltage being applied, and FIG. 9B shows an out-of-plane magnetization curve of the switching element at room temperature in the presence of voltage being applied. Further, FIG. 10A shows an in-plane magnetization curve of an example of a switching element including a laminated structure according to an embodiment of the present invention at room temperature in the absence of voltage being applied, and FIG. 10B shows an in-plane magnetization curve of the switching element at room temperature in the presence of voltage being applied. Further, FIG. 11 is a diagram showing changes in out-of-plane magnetization of an example of a switching element including a laminated structure according to an embodiment of the present invention along with voltage application.

As shown in FIG. 9A, when no voltage is applied, the out-of-plane magnetization curve has a substantially rectangular shape on a central side near a magnetic field 0 Oe. This shows that the magnetization orientation is in the perpendicular direction. On the other hand, as shown in FIG. 9B, when voltage that generates an electric field of 10 kV/cm is applied, the out-of-plane magnetization has an obliquely-deformed shape. This shows that the magnetization orientation has switched to the in-plane direction.

Meanwhile, as shown in FIG. 10A, when no voltage is applied, the in-plane magnetization has an obliquely-deformed shape. This shows that the magnetization orientation is in the perpendicular direction. On the other hand, as shown in FIG. 10B, when voltage that generates an electric field of 10 kV/cm is applied, the in-plane magnetization curve has a substantially rectangular shape on a central side near a magnetic field 0 Oe. This shows that the magnetization orientation has switched to the in-plane direction.

Thus, an analysis of the out-of-plane magnetization curves shown in FIGS. 9A and 9B and the in-plane magnetization curves shown in FIGS. 10A and 10B shows that when no voltage is applied, the magnetization orientation is out-of-plane magnetization orientation and that application of voltage causes the magnetization orientation to switch from out-of-plane magnetization orientation to in-plane magnetization orientation. This demonstrates that the magnetization orientation of the switching element 130 including the laminated structure 110 of the present example can be switched from out-of-plane magnetization orientation to in-plane magnetization orientation by applying voltage.

Furthermore, as shown in the lower section of the graph of FIG. 11, the periodically-repeated turning on and turning off of voltage application to the switching element 130 of the present example causes such periodic modulation of a magnetization signal as that shown in the upper section of the graph of FIG. 11 to be observed in no magnetic fields state in correspondence with the turning on and turning off of voltage. This periodic modulation of the magnetization signal corresponds to out-of-plane and in-plane magnetization switching entailed by voltage application, and demonstrates that a switching element 130 capable of controlling magnetization orientation in the out-of-plane or in-plane direction with voltage in no magnetic fields state can be configured.

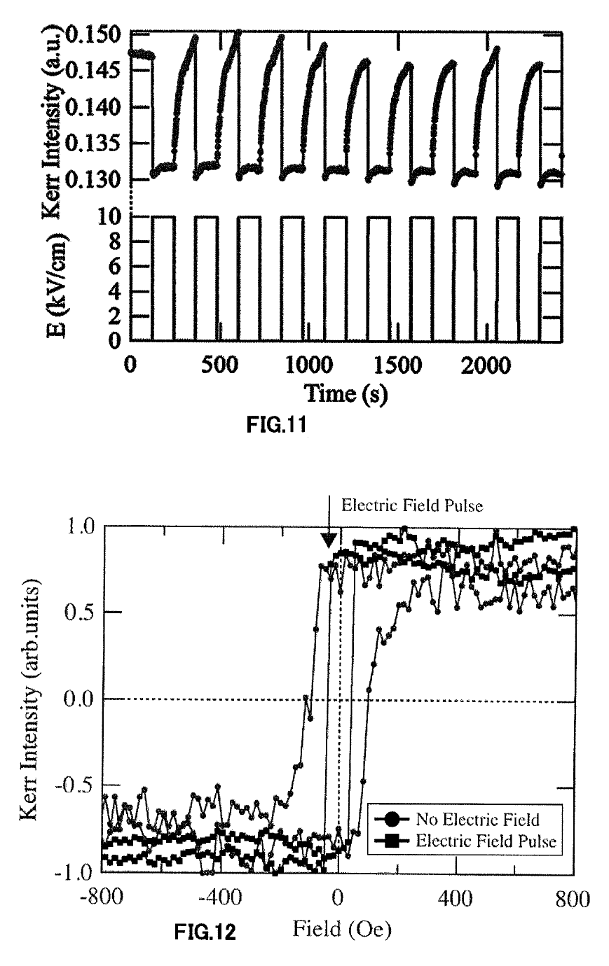

Next, the control of magnetization orientation by application of voltage to the switching element 130 of the present example is described with reference to the drawings. FIG. 12 is a diagram showing changes in out-of-plane magnetization in a case where control of reversal of magnetization between upward and downward out-of-plane directions by voltage has been performed on an example of a switching element including a laminated structure according to an embodiment of the present invention. It should be noted that, in FIG. 12, the data plot of black circular dots represents the magnetic field dependence of magnetization in the absence of voltage being applied, and the data plot of black quadrangular dots represents changes in out-of-plane magnetization in the presence of voltage applied in a magnetic field indicated by an arrow in the drawing.

As shown in FIG. 12, the magnetic coercivity in the absence of voltage being applied is approximately 100 Oe. Next, magnetization is recorded while the magnetic field is reduced from a positive saturated magnetization state. The magnetic field sweep is suspended at a predetermined negative minute value of −33 Oe. An electric field of 10 kV/cm with a pulse width of 1 second is applied. After that, magnetization was recorded while the magnetic field was further reduced to a negative saturated magnetization state.

The result is shown as the data plot of black quadrangular dots in FIG. 12. The data plot shows that, at −30 Oe, which is a magnetic field smaller than half the magnetic coercivity, magnetization is immediately reduced by applying voltage and the voltage application reversed magnetization from the upward perpendicular direction to the downward perpendicular direction. This shows that when a magnetic field whose strength continuously varies in a predetermined direction is further applied to the multilayer film layer 114 of the laminated structure 110 and the strength of the magnetic field changes from 0 to a predetermined negative minute value (−33 Oe in the present example), application of voltage makes it possible to control a 180-degree reversal of the magnetization orientation of the multilayer film layer from the upward perpendicular direction to the downward perpendicular direction.

It is to be noted that while the respective embodiments and respective examples of the present invention have been described in detail as mentioned above, one skilled in the art will easily understand that a large number of modifications can be made without substantively departing from the new matter and advantageous effect of the present invention. Accordingly, such modification examples are all to be considered included in the scope of the present invention.

For example, the term mentioned at least once along with a broader-sense or synonymous different term in the specification or the drawing can be replaced with the different term even anywhere in the specification or the drawing. In addition, a laminated structure, a switching element, and a magnetic device configurations, operation is also not limited to the descriptions in the respective embodiments of the present invention, but various modifications can be made.

### GLOSSARY OF DRAWING REFERENCES

10, 110 . . . a laminated structure, 11, 111 . . . a ferroelectric layer, 12,112 . . . a foundation layer, 13,113 . . . an intermediate layer, 14,114 . . . a multilayer film layer, 15, 15a, 15b, 15c, 115 . . . a ferromagnetic layer, 16, 16a, 16b, 16c, 116 . . . a non-magnetic layer, 17, 117 . . . a metal film layer, 20, 20a, 20b, 120 . . . a electrode, 22, 122 . . . a power supply, 30, 130 . . . a switching element, 100 . . . a magnetic head (a magnetic device), 200 . . . a spin transistor (a magnetic device), 300 . . . a polarization control light-emitting element (a magnetic device), SU . . . a heat treatment step, S12 . . . a foundation layer lamination step, S13 . . . an intermediate layer lamination step, S14 . . . a multilayer film layer lamination step, S15 . . . a metal film layer lamination step

1-13. (canceled)

14. A multiferroic laminated structure having ferroelectricity and ferromagnetism, comprising:
a ferroelectric layer made of a ferroelectric substance having the ferroelectricity with a domain structure;
a foundation layer composed mainly of a metal having a good lattice-matching property with the ferroelectric substance and laminated on a surface of the ferroelectric layer;
an intermediate layer composed mainly of a non-magnetic substance and laminated on a surface of the foundation layer; and
a ferromagnetic/non-magnetic multilayer film layer constituted by alternately laminating ferromagnetic layers and non-magnetic layers on a surface of the intermediate layer in at least three cycles, the ferromagnetic layers being composed mainly of a ferromagnetic substance and having magnetization oriented in a perpendicular direction, the non-magnetic layers being composed mainly of the non-magnetic substance.

15. The laminated structure according to claim 14, wherein the ferroelectric substance constituting the ferroelectric layer is barium titanate,
the metal constituting the foundation layer is iron,
the non-magnetic substance constituting the intermediate layer and the non-magnetic layers is copper, and
the ferromagnetic substance constituting the ferromagnetic layers is nickel.

16. The laminated structure according to claim 14, wherein the multilayer film layer is configured such that the non-magnetic layers are larger in thickness than the ferromagnetic layers.

17. A switching element comprising:
electrodes connected to a power supply; and
a laminated structure according to claim 14 provided between the electrodes.

18. The switching element according to claim 17, wherein application of voltage from the power supply enables switching of magnetization orientation of a multilayer film layer included in the laminated structure and composed of ferromagnetic layers and non-magnetic layers.

19. The switching element according to claim 18, wherein a magnetic field whose strength continuously varies in a predetermined direction is further applied to the multilayer film layer, and
when the strength of the magnetic field takes on a predetermined negative minute value, application of voltage from the power supply enables switching of magnetization orientation of the multilayer film layer.

20. The switching element according to claim 17, wherein a change of an environmental temperature at which the laminated structure is provided to a predetermined temperature enables switching of magnetization orientation of a multilayer film layer included in the laminated structure.

21. A magnetic device comprising a switching element according to claim 17.

22. The magnetic device according to claim 21, wherein the switching element is provided in at least any of a magnetic head, a spin transistor, a polarization control light-emitting element, and a micromotor.

23. A method for manufacturing a multiferroic laminated structure having ferroelectricity and ferromagnetism, comprising:
a heat treatment step of heat-treating a ferroelectric layer made of a ferroelectric substance having the ferroelectricity with a domain structure;
a foundation layer lamination step of laminating a foundation layer on a surface of the ferroelectric layer by epitaxially growing the foundation layer, the foundation layer being composed mainly of a metal having a good lattice-matching property with the ferroelectric substance;
an intermediate layer lamination step of laminating an intermediate layer on a surface of the foundation layer by epitaxially growing the intermediate layer, the intermediate layer being composed mainly of a non-magnetic substance; and
a multilayer film layer lamination step of laminating a ferromagnetic/non-magnetic multilayer film layer on a surface of the intermediate layer by epitaxially growing the multilayer film layer, the multilayer film layer being constituted by alternately laminating ferromagnetic layers and non-magnetic layers in at least three cycles, the ferromagnetic layers being composed mainly of a ferromagnetic substance and having magnetization oriented in a perpendicular direction, the non-magnetic layers being composed mainly of the non-magnetic substance.

24. The method according to claim 23, wherein the ferroelectric substance constituting the ferroelectric layer is barium titanate,
the metal constituting the foundation layer is iron,
the non-magnetic substance constituting the intermediate layer and the non-magnetic layers is copper, and
the ferromagnetic substance constituting the ferromagnetic layers is nickel.

25. The laminated structure according to claim 14, wherein the thickness of the non-magnetic layer is less than 10 nm.

26. The method according to claim 23, wherein in the multilayer film layer lamination step, the thickness of the non-magnetic layer is laminated to be less than 10 nm.
